(19) United States
(12) Patent Application Publication
(10) Pub. No.: US 2002/0164868 A1
(43) Pub. Date: Nov. 7, 2002

(54) Method for forming a silicon dioxide-low k dielectric stack

(76) Inventors: Ting-Chang Chang, Hsin-Chu City (TW); Po-Tsun Liu, Hsin-Chu City (TW); Yi-Shien Mor, Taipei City (TW)

Correspondence Address: POWELL, GOLDSTEIN,, FRAZER & MURPHY LLP, P.O. BOX 97223, WASHINGTON, DC, 20090-7223, US

(21) Appl. No.: 09/847,087

(22) Filed: May 2, 2001

(51) Int. Cl. H01L 21/4763

(52) U.S. Cl. 438/622; 438/624; 438/623

(57) ABSTRACT

A method for forming silicon dioxide-low k dielectric stack is provided. The present invention is characterized in that applying H₂ plasma on a low k dielectric layer formed on a conductive interconnect layer to cover dangling bonds on the surface of the low k dielectric layer. Thereby, preventing the reaction between the low k dielectric layer and oxygen gas employed in a subsequent process for forming a cap layer of silicon dioxide occurring, and thus prohibiting oxygen gas damaging the low k dielectric layer.

### BACKGROUND OF THE INVENTION

1. Field of the Invention

The present invention relates to a multilevel interconnect process, more particularly to a process associating metal lines with low k dielectrics.

2. Description of the Prior Art

The shrinkage of the dimension of semiconductor devices is accompanied with mass-production of the ultra large semiconductor integration's (ULSI) wafers with high speed, high integration and low power consumption. In order to reduce delay of signal transmission, for example, RC delay, generated by metal interconnect system, conductive lines with low resistance, such as metal lines formed of copper or aluminum, and low k dielectrics are applied to multilevel interconnects. There are many kinds of low k dielectrics. A kind of low k dielectric of porous silicate with a dielectric constant smaller than 2.0 has been employed in the deep sub-micron process. However, the adsorption of gaseous water constantly occurs in the IC manufacturing process employing low k dielectrics, especially porous dielectrics.

FIG. 1 depicts a schematic cross-sectional view of a prior stacked structure formed of a metal interconnect layer and a porous low k dielectric layer. A liner layer of silicon dioxide 11 is formed between a metal interconnect layer 10 and a low k dielectric layer 12 to increase adhesion between them. In addition, a low temperature cap layer of silicon dioxide 13 is generally deposited on the low k dielectric layer 12 to prevent the photoresist layer from directly contacting with the low k dielectric layer 12. Thereby, the problem of adsorption of gaseous water in the subsequent process for forming the metal plug is avoided. The low temperature cap layer of silicon dioxide 13 is formed by the chemical reaction with TEOS/O₂ as reaction gases at the temperature about 450° C. However, during the process for forming the low temperature cap layer of silicon dioxide 13, oxygen gas (O₂) would react with the underlying low k dielectric layer 12, for example, a porous low k dielectric layer or an organic low k dielectric layer containing C—H bonds. Oxygen gas would associate with dangling bonds on the surface of the porous low k dielectric layer so as to damage its dielectric property. Alternatively, oxygen gas interrupts C—H bonds of the organic low k dielectric layer to generate many dangling bonds. The dangling bonds would associate with oxygen gas, and then damage the dielectric property of the organic low k dielectric layer. Consequently, the leakage current of the low k dielectric layer is increased. Then, a reliability issue of semiconductor devices is happened.

Accordingly, it is an intention to provide a method for forming an improved stacked structure formed of a cap layer of silicon dioxide and a low k dielectric layer to alleviate drawbacks encountered in the conventional method.

### SUMMARY OF THE INVENTION

It is an objective of the present invention to provide a method for forming a silicon dioxide-low k dielectric stack, in which H₂ plasma is applied on a low k dielectric layer prior to forming a cap layer of silicon dioxide thereon. Thereby, preventing the reaction between the low k dielectric layer and oxygen gas employed in the subsequent process for forming the cap layer of silicon dioxide occurring. Then, the damage of the low k dielectric layer and the increasing of the leakage current of the low k dielectric layer are avoided.

Another objective of the present invention is to provide a method for forming a silicon dioxide-porous low k dielectric stack, in which H₂ plasma is applied on a porous low k dielectric layer prior to forming a cap layer of silicon dioxide thereon. Thereby, the dangling bonds on the surface of the porous low k dielectric layer are covered by way of the surface treatment with H₂ plasma. And then, the increasing of the leakage current of the porous low k dielectric layer due to adsorption of gaseous water is prevented.

In order to achieve the above objectives, the present invention provides a method for forming silicon dioxide-low k dielectric stack. A conductive interconnect layer is provided. Forming a low k dielectric layer over the conductive interconnect layer. Applying H₂ plasma on the low k dielectric layer. Forming a cap layer of silicon dioxide on the low k dielectric layer after applying H₂ plasma.

### BRIEF DESCRIPTION OF THE DRAWINGS

The present invention can be best understood through the following description and accompanying drawings, wherein:

FIG. 1 depicts a schematic cross-sectional view of a prior stacked structure formed of a cap layer of silicon dioxide and a low k dielectric layer;

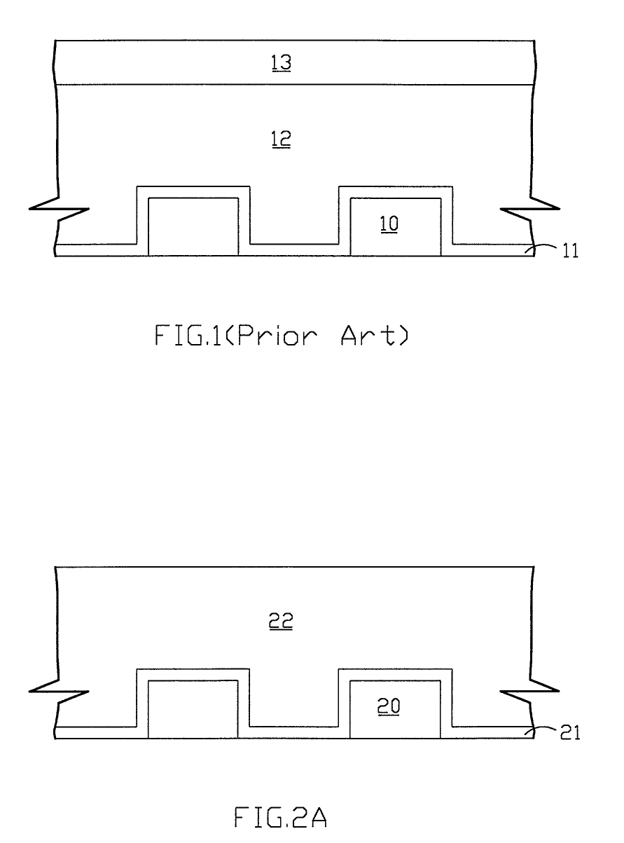

FIG. 2A to FIG. 2C depicts schematic cross-sectional views of various steps for forming a stacked structure formed of a cap layer of silicon dioxide and a low k dielectric layer according to one embodiment of the present invention; and

FIG. 3 is a diagram of the leakage current density of a low k dielectric layer vs. the electric field applied thereon, which shows variation of the leakage current density with/without applying H₂ plasma on the low k dielectric layer according to the present invention.

### DESCRIPTION OF THE PREFERRED EMBODIMENTS

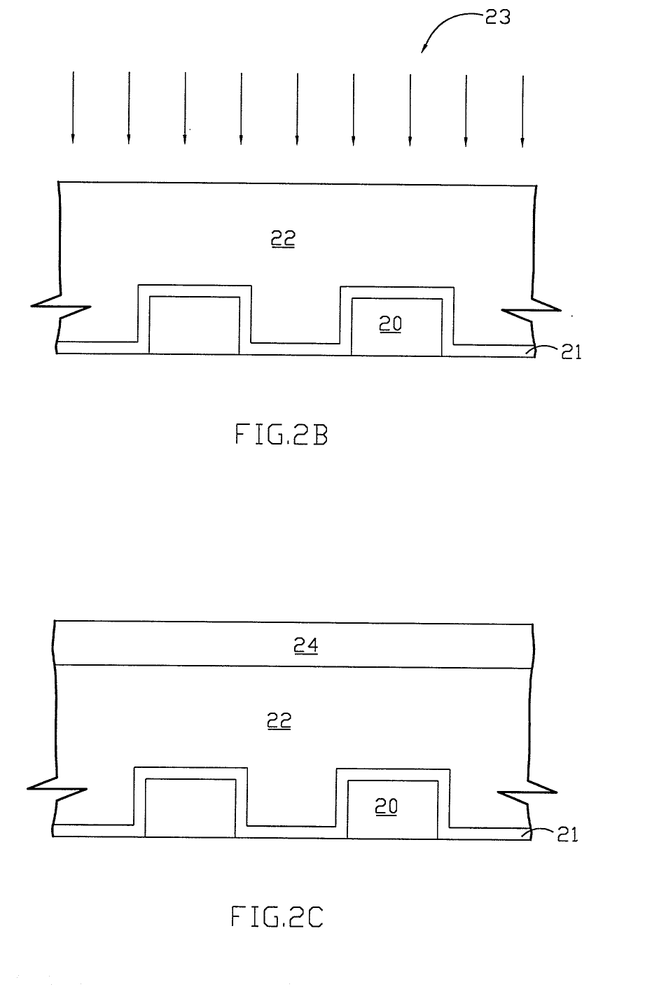

Referring to FIG. 2A, a conductive interconnect layer 20, such as an interconnect layer comprising aluminum lines, is firstly provided. A low k dielectric layer 22 is formed on the conductive interconnect layer 20. The low k dielectric layer 22 can be a porous low k dielectric layer formed by spin-on, such as porous silicate. Alternately, the low k dielectric layer 22 can be an organic low k dielectric layer formed by spin-on, selected from the group consisting of polyimides, polyimide siloxane, fluoro-polyimide, polysiloxane and Teflon-AF. Besides, the low k dielectric layer of parylene-F or parylene-N formed by chemical vapor deposition method is also suitable for the present invention.

A liner layer of silicon dioxide 21 is preferably formed between the low k dielectric layer 22 and the conductive interconnect layer 20 to improve adhesion between them. The liner layer of silicon dioxide 21 is preferably formed at a low temperature, for example below about 500° C. The liner layer of silicon dioxide 21 can be formed by way of plasma enhanced chemical vapor deposition method (PECVD), utilizing SiH₄ as reaction gas at the temperature of about 300˜400° C. under the operation pressure of about 1˜10 torr. Besides, the liner layer of silicon dioxide 21 also can be formed by way of plasma enhanced chemical vapor deposition method utilizing TEOS/O₂ as reaction gases.

Referring to FIG. 2B, H₂ plasma 23 is applied on the low k dielectric layer 22. The H₂ plasma 23 can be generated under the following conditions: about 150˜400 mtorr in pressure, about 150˜350° C. in temperature, about 100˜250 watt in power, and about 100˜350 sccm for the flow rate of gas. The H₂ plasma 23 is preferably generated under the conditions: about 300 mtorr in pressure, about 300° C. in temperature, about 100 watt in power and about 200 sccm for the flow rate of gas. The time for applying H₂ plasma on the low k dielectric layer 22 can be about 3 minutes or about 5 minutes. The dangling bonds on the surface of the low k dielectric layer 22 are covered after applying H₂ plasma, and thus do not directly contact with oxygen gas employed in the subsequent process for forming a cap layer of silicon dioxide 24 (as shown in FIG. 2C).

Referring to FIG. 2C, a cap layer of silicon dioxide 24 with a thickness about 300˜500 angstroms is formed on the low k dielectric layer 22 after H₂ plasma treatment. Therefore, a stacked structure formed of the cap layer of silicon dioxide 24 and the low k dielectric layer 22 is obtained. Depending on the melting point of metal lines of the conductive interconnect layer 20 and thermal stability of the low k dielectric layer 22, the cap layer of silicon dioxide 24 is formed at the temperature lower than about 450° C. For example, the cap layer of silicon dioxide 24 can be formed by way of high density plasma chemical vapor deposition method (HDPCVD), utilizing TEOS/O₂ as reaction gases at the temperature of about 200˜250° C. Alternately, the cap layer of silicon dioxide 24 can be formed by way of plasma enhanced chemical vapor deposition method (PECVD) at the temperature of about 250˜300° C.

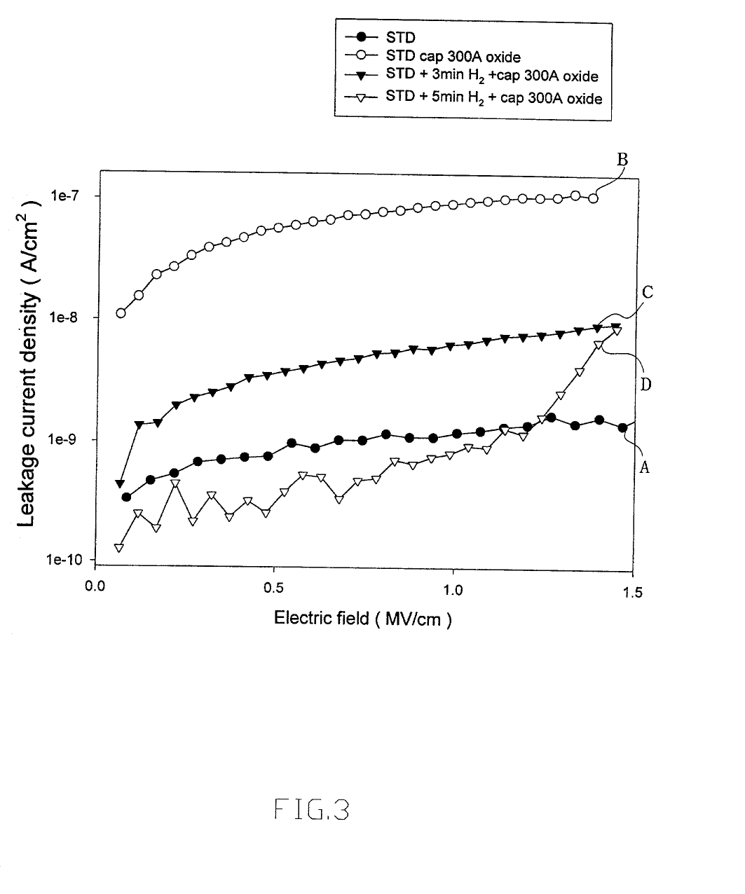

FIG. 3 is a diagram of the leakage current density of the porous low k dielectric layer 22 vs. electric field applied thereon. Curve A shows variation of the leakage current density vs. electric field, in which the porous low k dielectric layer 22 is not performed surface treatment with H₂ plasma 23 and without the cap layer of silicon dioxide 24 formed thereon. Curve B shows variation of the leakage current density vs. electric field, in which the porous low k dielectric layer 22 is not performed surface treatment with H₂ plasma, but provided with the cap layer of silicon dioxide 24 in a thickness about 300 angstroms. Curve C shows variation of the leakage current density vs. electric field, in which the porous low k dielectric layer 22 is performed surface treatment with H₂ plasma for about 3 minutes and then the cap layer of silicon dioxide 24 in a thickness about 300 angstroms is formed thereon. Curve D shows variation of the leakage current density vs. electric field, in which the porous low k dielectric layer 22 is performed surface treatment with H₂ plasma for about 5 minutes and then the cap layer of silicon dioxide 24 in a thickness about 300 angstroms is formed thereon.

Comparing with curve A, curve B shows the leakage current of the porous low k dielectric layer 22 without H₂ plasma treatment, but with the cap layer of silicon dioxide 24 formed thereon, is abruptly increased. The increasing of the leakage current results from the damage of the porous low k dielectric layer 22 by oxygen gas during the process for forming the cap layer of silicon dioxide 24. However, curve C and D show the leakage current of the porous low k dielectric layer 22 with H₂ plasma treatment is decreased. The leakage current is largely decreased when the time for applying H₂ plasma on the porous low k dielectric layer 22 is increased. And, H₂ plasma treatment even recovers the inherent leakage current of the porous low k dielectric layer 22 without the cap layer of silicon dioxide 24 formed thereon. The dielectric constant of the porous low k dielectric layer 22 is also maintained with the value about 1.9.

Therefore, H₂ plasma treatment can effectively prevent oxygen gas from damaging the low k dielectric layer during the process for forming the cap layer of silicon dioxide. The present invention provides a process for forming a silicon dioxide-low k dielectric stack with highly reliability.

The preferred embodiments are only used to illustrate the present invention, not intended to limit the scope thereof. Many modifications of the preferred embodiments can be made without departing from the spirit of the present invention.

What is claimed is:

1. A method for forming a silicon dioxide-low k dielectric stack, comprising:
providing a conductive interconnect layer;
forming a low k dielectric layer over said conductive interconnect layer;
applying H₂ plasma on said low k dielectric layer; and
forming a cap layer of silicon dioxide on said low k dielectric layer subsequent to applying said H₂ plasma.

2. The method of claim 1, wherein said conductive interconnect layer comprises metal lines formed of aluminum.

3. The method of claim 2, further comprising forming a liner layer of silicon dioxide between said conductive interconnect layer and said low k dielectric layer.

4. The method of claim 3, wherein said liner layer of silicon dioxide is formed by way of plasma enhanced chemical vapor deposition method (PECVD), utilizing SiH₄ as reaction gas at the temperature of about 300˜400° C. under the operation pressure of about 1˜10 torr.

5. The method of claim 3, wherein said liner layer of silicon dioxide is formed by way of plasma enhanced chemical vapor deposition method utilizing TEOS/O₂ as reaction gases.

6. The method of claim 1, wherein said low k dielectric layer comprises a porous low k dielectric layer.

7. The method of claim 6, wherein said porous low k dielectric layer comprises porous silicate.

8. The method of claim 6, wherein said porous low k dielectric layer is formed by spin-on.

9. The method of claim 7, wherein said porous low k dielectric layer is formed by spin-on.

10. The method of claim 1, wherein said low k dielectric layer is formed of the material selected from the group consisting of polyimides, polyimide siloxane, fluoro-polyimide, polysiloxane, parylene-N, parylene-F and Teflon AF.

11. The method of claim 1, wherein said H₂ plasma is generated under the conditions of about 150˜400 mtorr in pressure, about 150˜350° C. at temperature, about 100˜250 watt in power and about 100˜350 sccm for the flow rate of gas.

12. The method of claim 11, wherein said H₂ plasma is applied on said low k dielectric layer for about 3 minutes.

13. The method of claim 11, wherein said H₂ plasma is applied on said low k dielectric layer for about 5 minutes.

14. The method of claim 1, wherein said H₂ plasma is generated under the conditions of about 300 mtorr in pressure, about 300° C. at temperature, about 100 watt in power and about 200 sccm for the flow rate of gas.

15. The method of claim 14, wherein said H₂ plasma is applied on said low k dielectric layer for about 3 minutes.

16. The method of claim 14, wherein said H₂ plasma is applied on said low k dielectric layer for about 5 minutes.

17. The method of claim 1, wherein said cap layer of silicon dioxide is about 300˜500 angstroms in thickness.

18. The method of claim 1, wherein said cap layer of silicon dioxide is formed by way of high density plasma chemical vapor deposition method (HDPCVD), utilizing TEOS/O₂ as reaction gas at the temperature of about 200˜250° C.

19. The method of claim 1, wherein said cap layer of silicon dioxide is formed by way of plasma enhanced chemical vapor deposition method (PECVD), utilizing TEOS/O₂ as reaction gas at the temperature of about 250˜300° C.

20. A method for forming a silicon dioxide-porous low k dielectric stack, comprising:
providing an interconnect layer comprising aluminum metal lines;
forming a liner layer of silicon dioxide on said interconnect layer;
forming a porous low k dielectric layer on said liner layer of silicon dioxide;
applying H₂ plasma on said porous low k dielectric layer; and
forming a cap layer of silicon dioxide on said porous low k dielectric layer subsequent to applying said H₂ plasma.

21. The method of claim 20, wherein said liner layer of silicon dioxide is formed by way of plasma enhanced chemical vapor deposition method (PECVD), utilizing SiH₄ as reaction gas at the temperature of about 300˜400° C. under the operation pressure of about 1˜10 torr.

22. The method of claim 20, wherein said liner layer of silicon dioxide is formed by way of plasma enhanced chemical vapor deposition method utilizing TEOS/O₂ as reaction gases.

23. The method of claim 20, wherein said porous low k dielectric layer comprises porous silicate.

24. The method of claim 20, wherein said porous low k dielectric layer is formed by spin-on.

25. The method of claim 23, wherein said porous low k dielectric layer is formed by spin-on.

26. The method of claim 20, wherein said H₂ plasma is generated under the conditions of about 150˜400 mtorr in pressure, about 150˜350° C. at temperature, about 100˜250 watt in power and about 100˜350 sccm for the flow rate of gas.

27. The method of claim 26, wherein said H₂ plasma is applied on said porous low k dielectric layer for about 3 minutes.

28. The method of claim 26, wherein said H₂ plasma is applied on said porous low k dielectric layer for about 5 minutes.

29. The method of claim 20, wherein said H₂ plasma is generated under the conditions of about 300 mtorr in pressure, about 30020 C. at temperature, about 100 watt in power and about 200 sccm for the flow rate of gas.

30. The method of claim 29, wherein said H₂ plasma is applied on said porous low k dielectric layer for about 3 minutes.

31. The method of claim 29, wherein said H₂ plasma is applied on said porous low k dielectric layer for about 5 minutes.

32. The method of claim 20, wherein said cap layer of silicon dioxide is about 300˜500 angstroms in thickness.

33. The method of claim 20, wherein said cap layer of silicon dioxide is formed by way of high density plasma chemical vapor deposition method (HDPCVD), utilizing TEOS/O₂ as reaction gas at the temperature of about 200˜250° C.

34. The method of claim 20, wherein said cap layer of silicon dioxide is formed by way of plasma enhanced chemical vapor deposition method (PECVD), utilizing TEOS/O₂ as reaction gas at the temperature of about 250˜300° C.
